(19) United States
(12) Patent Application Publication
(10) Pub. No.: US 2026/0344495 A1
(43) Pub. Date: Oct. 29, 2026

(54) SEMICONDUCTOR DEVICE

(71) Applicant: ROHM CO., LTD., Kyoto-shi (JP)

(72) Inventor: Toshiyuki NAGAI, Kyoto-shi (JP)

(21) Appl. No.: 19/705,888

(22) Filed: Jun. 12, 2026

Related U.S. Application Data
(63) Continuation of application No. PCT/JP2024/041640, filed on Nov. 25, 2024.

(30) Foreign Application Priority Data
Dec. 20, 2023 (JP) 2023-214483

(51) Int. Cl. H10W 72/00; H10W 74/10

(52) U.S. Cl. CPC H10W 72/834; H10W 72/823; H10W 74/111

(57) ABSTRACT

A semiconductor device includes one or more switching elements, a support substrate supporting the one or more switching elements, one or more leads, and a sealing resin. The sealing resin covers the one or more switching elements, a part of the support substrate, and a part of each of the one or more leads. The support substrate includes an exposed surface exposed from the sealing resin on a first side in a first direction that is a thickness direction of the support substrate. Each of the one or more leads includes a terminal including a mounting surface facing a second side in the first direction.

### TECHNICAL FIELD

The present disclosure relates to a semiconductor device.

### BACKGROUND ART

JP-A-2022-123260 discloses an example of a conventional semiconductor device. The semiconductor device disclosed in the document includes a semiconductor element that performs a switching operation, a lead, and a sealing resin. A portion of the lead that protrudes from the sealing resin is bent, and the distal end faces in the thickness direction.

### BRIEF DESCRIPTION OF THE DRAWINGS

FIG. 1 is a plan view of a semiconductor device according to a first embodiment of the present disclosure.

FIG. 2 is a front view of the semiconductor device according to the first embodiment of the present disclosure.

FIG. 3 is a rear view of the semiconductor device according to the first embodiment of the present disclosure.

FIG. 4 is a right side view of the semiconductor device according to the first embodiment of the present disclosure.

FIG. 5 is a left view of the semiconductor device according to the first embodiment of the present disclosure.

FIG. 6 is a bottom view of the semiconductor device according to the first embodiment of the present disclosure.

FIG. 7 is a partial bottom view of the semiconductor device according to the first embodiment of the present disclosure.

FIG. 8 is a plan view of a switching element of the semiconductor device according to the first embodiment of the present disclosure.

FIG. 9 is a partial enlarged sectional view of the semiconductor device according to the first embodiment of the present disclosure.

FIG. 10 is a sectional view taken along line X-X in FIG. 7.

FIG. 11 is a sectional view taken along line XI-XI in FIG. 7.

FIG. 12 is a sectional view taken along line XII-XII in FIG. 7.

FIG. 13 is a sectional view taken along line XIII-XIII in FIG. 7.

FIG. 14 is a sectional view taken along line XIV-XIV in FIG. 7.

FIG. 15 is a circuit diagram of the semiconductor device according to the first embodiment of the present disclosure.

FIG. 16 is a partial bottom view of a first variation of the semiconductor device according to the first embodiment of the present disclosure.

FIG. 17 is a sectional view of a second variation of the semiconductor device according to the first embodiment of the present disclosure.

FIG. 18 is a sectional view of a third variation of the semiconductor device according to the first embodiment of the present disclosure.

FIG. 19 is a sectional view of a fourth variation of the semiconductor device according to the first embodiment of the present disclosure.

FIG. 20 is a partial enlarged sectional view of a fifth variation of the semiconductor device according to the first embodiment of the present disclosure.

FIG. 21 is a partial enlarged sectional view of a sixth variation of the semiconductor device according to the first embodiment of the present disclosure.

FIG. 22 is a bottom view of a seventh variation of the semiconductor device according to the first embodiment of the present disclosure.

FIG. 23 is a sectional view of an eighth variation of the semiconductor device according to the first embodiment of the present disclosure.

FIG. 24 is a partial bottom view of a semiconductor device according to a second embodiment of the present disclosure.

FIG. 25 is a sectional view taken along line XXV-XXV in FIG. 24.

FIG. 26 is a partial enlarged sectional view of the semiconductor device according to the second embodiment of the present disclosure.

FIG. 27 is a sectional view taken along line XXVII-XXVII in FIG. 24.

FIG. 28 is a circuit diagram of the semiconductor device according to the second embodiment of the present disclosure.

### DETAILED DESCRIPTION

The following describes preferred embodiments of the present disclosure in detail with reference to the drawings.

In the present disclosure, the terms such as “first”, “second”, and “third” are used merely as labels and are not intended to impose ordinal requirements on the items to which these terms refer.

In the description of the present disclosure, the expression “An object A is formed in an object B”, and “An object A is formed on an object B” imply the situation where, unless otherwise specifically noted, “the object A is formed directly in or on the object B”, and “the object A is formed in or on the object B, with something else interposed between the object A and the object B”. Likewise, the expression “An object A is disposed in an object B”, and “An object A is disposed on an object B” imply the situation where, unless otherwise specifically noted, “the object A is disposed directly in or on the object B”, and “the object A is disposed in or on the object B, with something else interposed between the object A and the object B”. Further, the expression “An object A is located on an object B” implies the situation where, unless otherwise specifically noted, “the object A is located on the object B, in contact with the object B”, and “the object A is located on the object B, with something else interposed between the object A and the object B”. Still further, the expression “An object A overlaps with an object B as viewed in a certain direction” implies the situation where, unless otherwise specifically noted, “the object A overlaps with the entirety of the object B”, and “the object A overlaps with a portion of the object B”. Furthermore, in the description of the present disclosure, the expression “A surface A faces (one side or the other side) in a direction B” is not limited to the situation where the angle of the surface A to the direction B is 90° and includes the situation where the surface A is inclined with respect to the direction B.

### First Embodiment

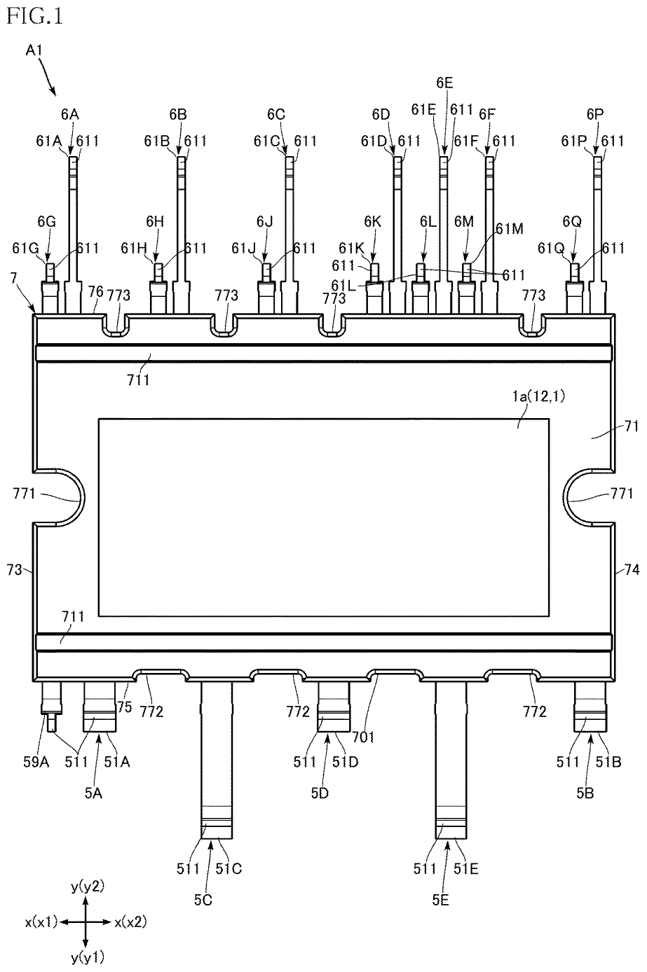

FIGS. 1 to 15 show a semiconductor device according to a first embodiment of the present disclosure. The semiconductor device A1 of the present embodiment includes one or more switching elements 2, a support substrate 1, one or more leads 5, and a sealing resin 7. The semiconductor device A1 may include a plurality of first conductive connecting members 81, a plurality of second conductive connecting members 82, and a thermistor 87.

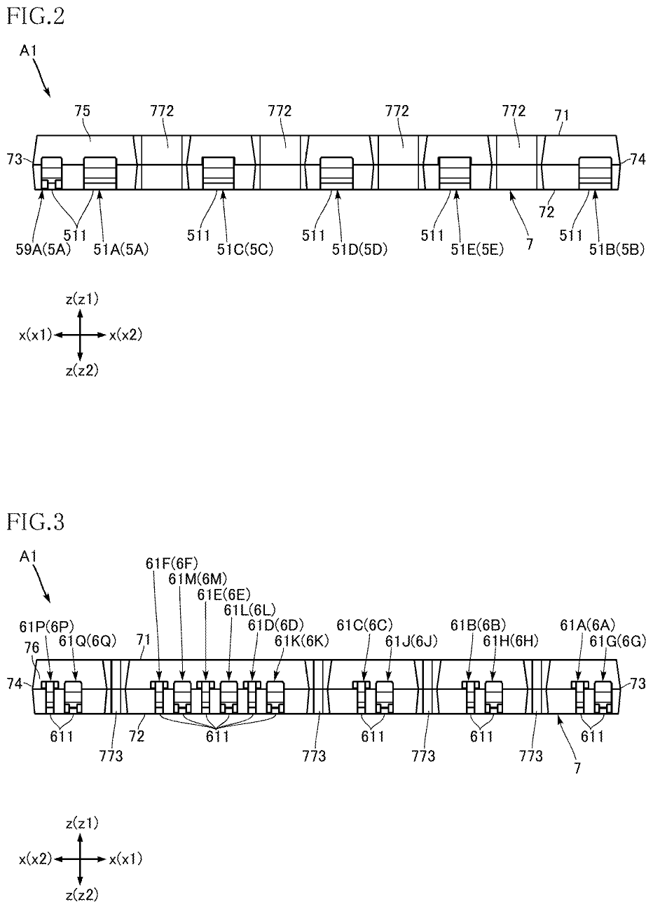

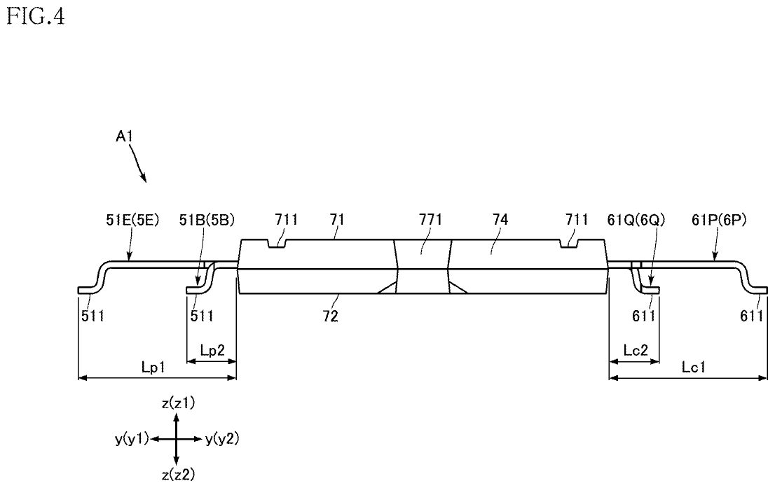

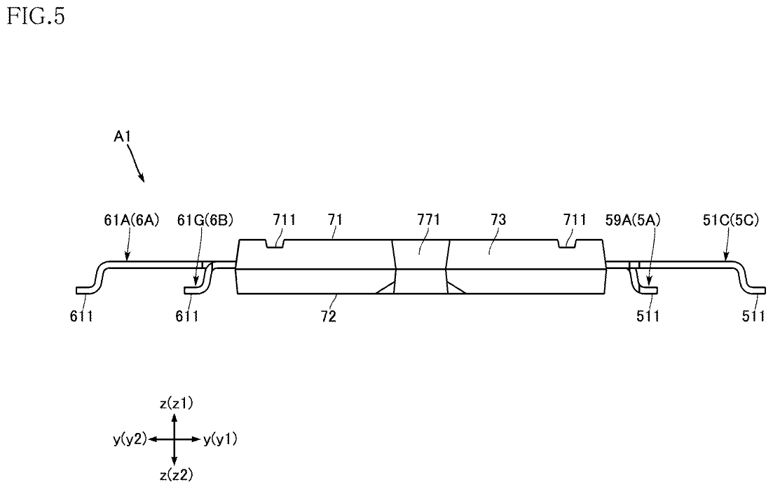

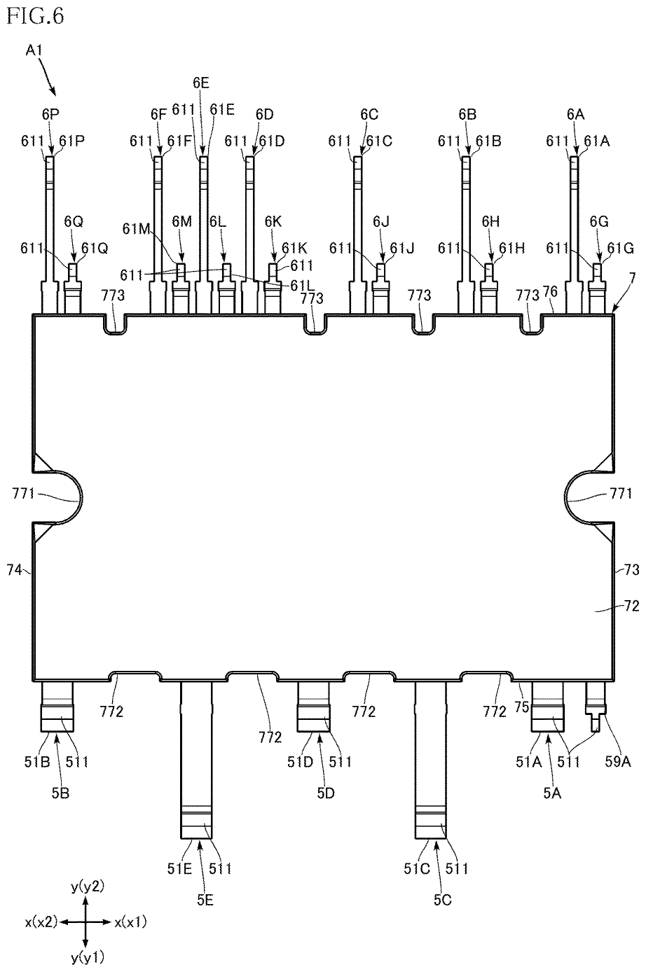

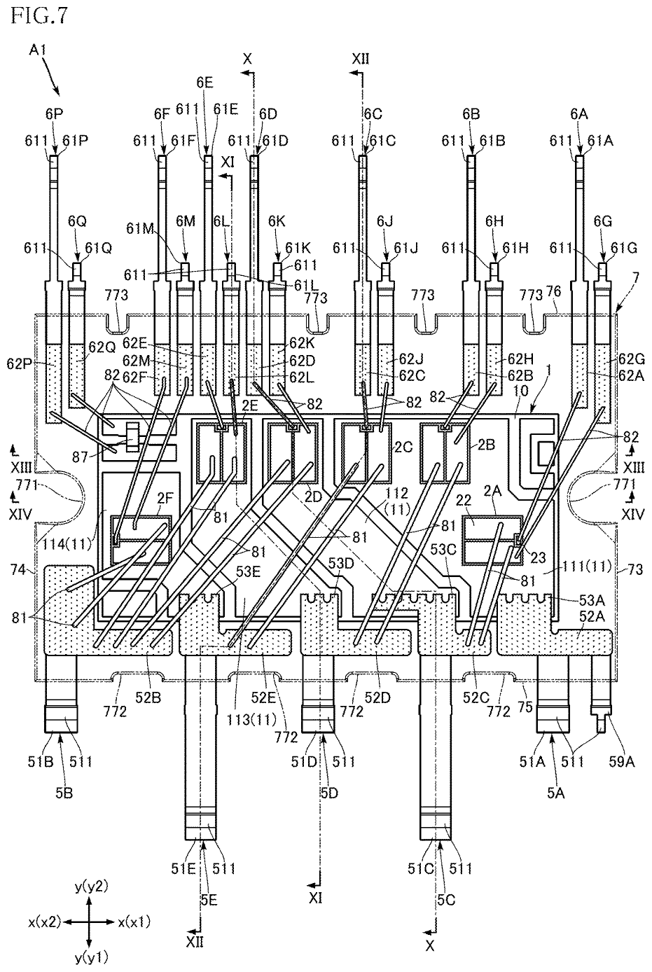

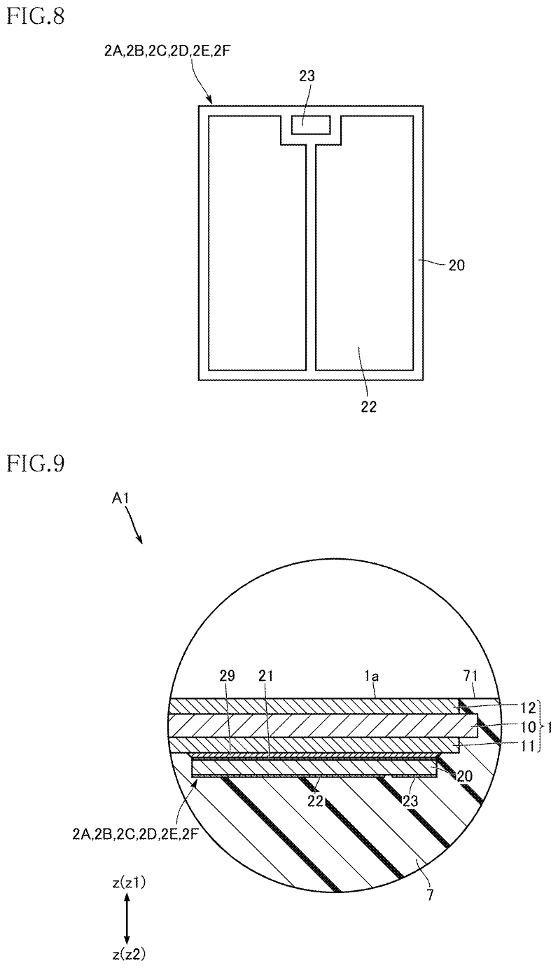

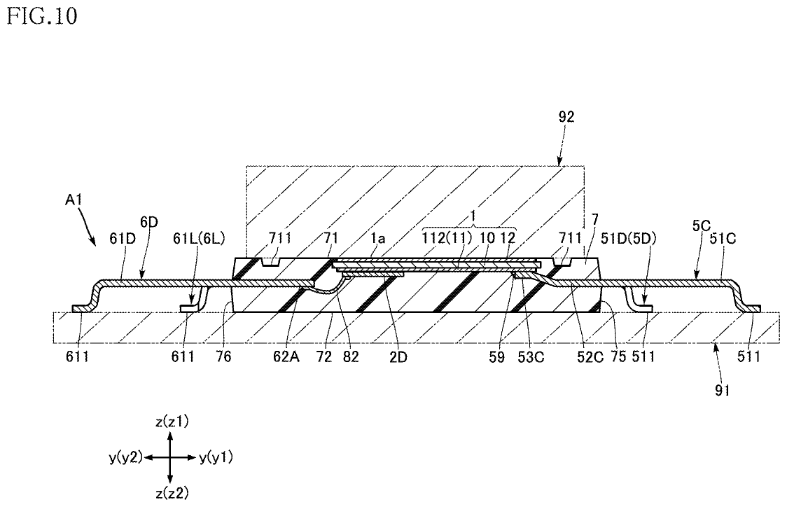

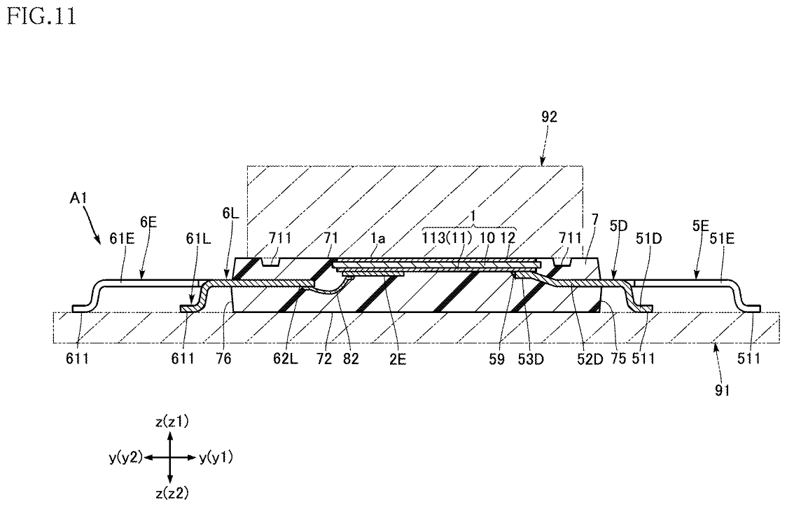

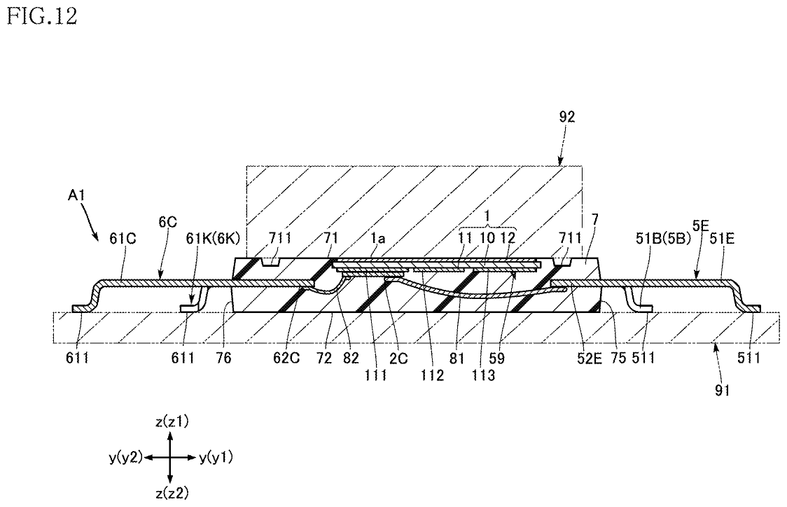

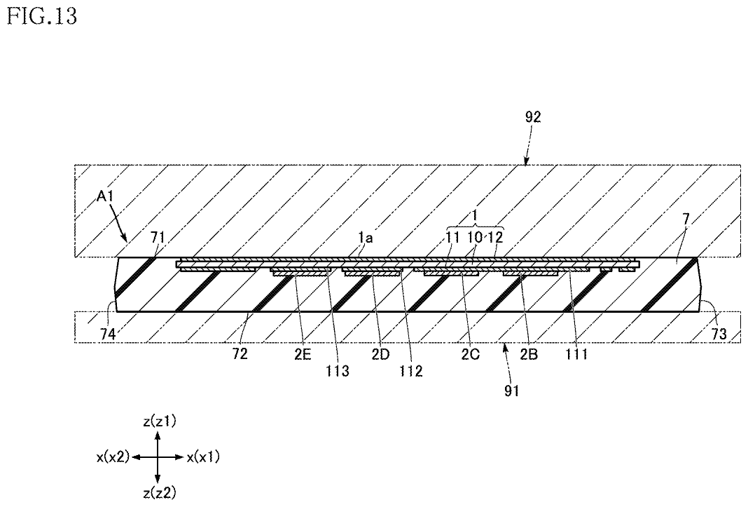

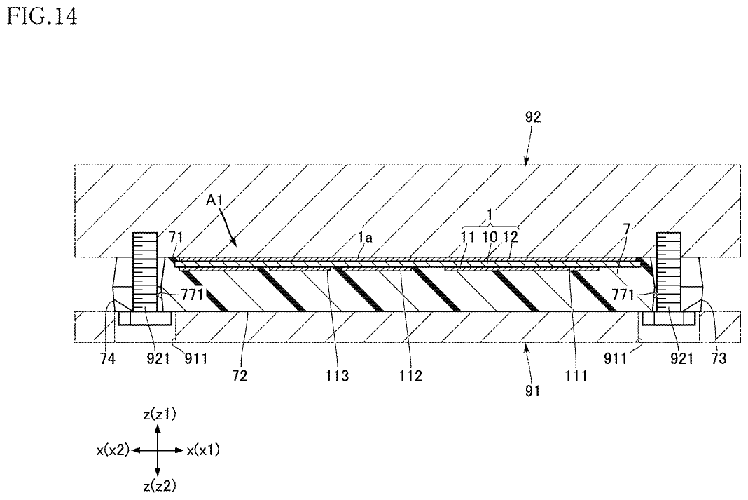

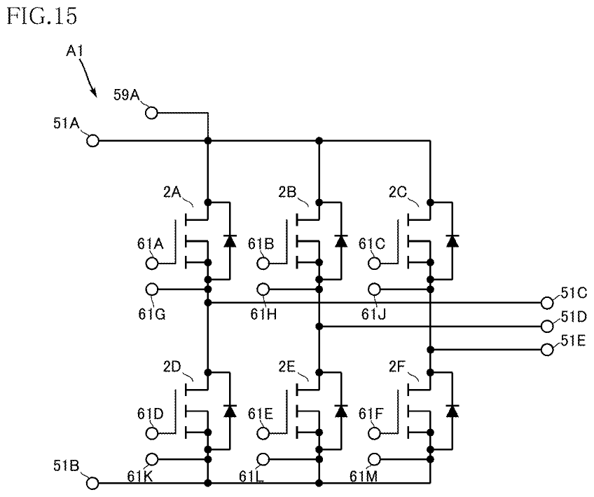

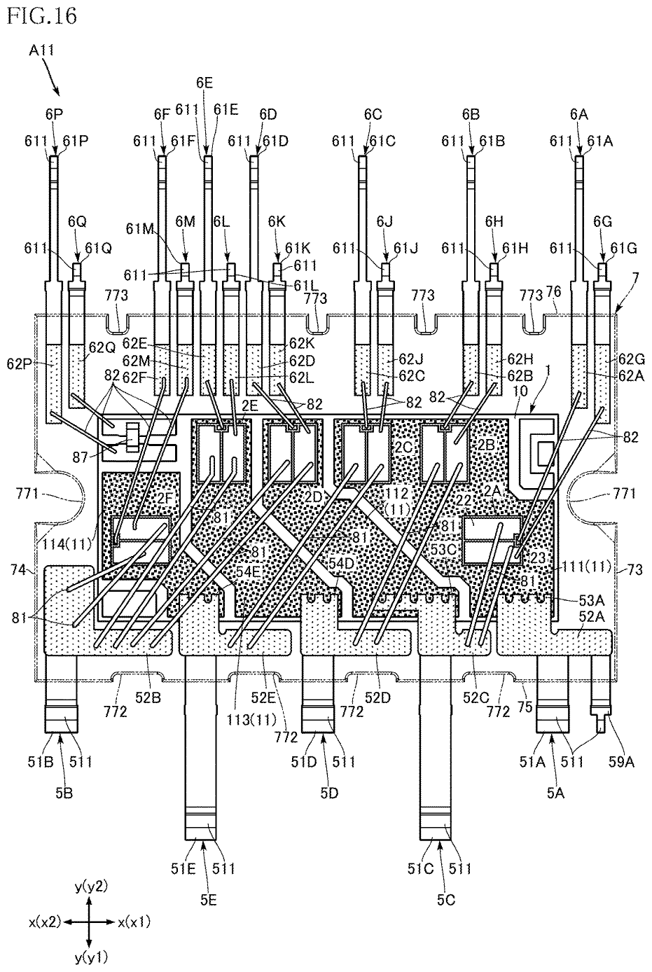

FIG. 1 is a plan view of the semiconductor device A1. FIG. 2 is a front view of the semiconductor device A1. FIG. 3 is a rear view of the semiconductor device A1. FIG. 4 is a right side view of the semiconductor device A1. FIG. 5 is a left side view of the semiconductor device A1. FIG. 6 is a bottom view of the semiconductor device A1. FIG. 7 is a partial bottom view of the semiconductor device A1. FIG. 8 is a plan view of a switching element of the semiconductor device A1. FIG. 9 is a partial enlarged sectional view of the semiconductor device A1. FIG. 10 is a sectional view taken along line X-X in FIG. 7. FIG. 11 is a sectional view taken along line XI-XI in FIG. 7. FIG. 12 is a sectional view taken along line XII-XII in FIG. 7. FIG. 13 is a sectional view taken along line XIII-XIII in FIG. 7. FIG. 14 is a sectional view taken along line XIV-XIV in FIG. 7. FIG. 15 is a circuit diagram of the semiconductor device A1. In FIG. 7, the outer shape of the sealing resin 7 is indicated by imaginary lines (chain double-dashed lines).

In the description of the semiconductor device A1, the thickness direction (plan-view direction) of the support substrate 1 is referred to as a “first direction z.” A direction orthogonal to the first direction z is an example of the “second direction” of the present disclosure, and is referred to as a “second direction y.” A direction orthogonal to the first direction z and the second direction y is referred to as a “third direction x.” One side in the first direction z is referred to as a first side z1, and the other side is referred to as a second side z2. One side in the second direction y is referred to as a first side y1, and the other side is referred to as a second side y2. One side in the third direction x is referred to as a first side x1, and the other side is referred to as a second side x2.

As shown in FIGS. 1, 7, and 9 to 14, the support substrate 1 supports one or more switching elements 2. The expression that the support substrate 1 supports the one or more switching elements 2 includes a configuration in which the one or more switching elements 2 are directly supported, for example, by being directly bonded to the support substrate 1, and a configuration in which the one or more switching elements 2 are indirectly supported with another member interposed between the one or more switching elements 2 and the support substrate 1.

The specific configuration of the support substrate 1 is not particularly limited. The support substrate 1 may be provided, for example, by a DBC (Direct Bonded Copper) substrate or an AMB (Active Metal Brazing) substrate. In the present embodiment, the support substrate 1 includes an insulating layer 10, a first metal layer 11, and a second metal layer 12. The support substrate 1 has an exposed surface 1a. The exposed surface 1a faces the first side z1 in the first direction z. The thickness of the support substrate 1 (dimension in the first direction z) is not particularly limited, and may be, for example, 0.4 mm or more and 3.0 mm or less. When the semiconductor device A1 is used, the exposed surface 1a may be brought into contact with or bonded to a heat sink 92, for example.

The insulating layer 10 is made of an insulating material, and may be made of, for example, ceramics having excellent thermal conductivity. Examples of such ceramics include silicon nitride (SiN) and alumina (Al₂O₃). The insulating layer 10 is not limited to ceramics, and may be, for example, an insulating resin sheet. The shape of the insulating layer 10 is not particularly limited, and may be, for example, rectangular in a plan view. In the present embodiment, the insulating layer 10 has an elongated rectangular shape whose longitudinal direction is the third direction x as viewed in the first direction z. The thickness of the insulating layer 10 is not particularly limited, and may be, for example, 0.05 mm or more and 1.0 mm or less.

The first metal layer 11 is located on the second side z2 in the first direction z relative to the insulating layer 10. The constituent material of the first metal layer 11 includes, for example, a metal such as copper (Cu). The constituent material may include, for example, aluminum (Al) instead of copper. The thickness of the first metal layer 11 is not particularly limited, and may be, for example, 0.1 mm or more and 1.5 mm or less.

The first metal layer 11 may include a first portion 111, a second portion 112, a third portion 113, and a fourth portion 114. The surfaces of the first portion 111 to the fourth portion 114 may be plated with, for example, silver (Ag).

The first portion 111 is located closer to the first side x1 in the third direction x. The second portion 112 is located on the second side x2 in the third direction x relative to the first portion 111 and is adjacent to the first portion 111. The third portion 113 is located on the second side x2 in the third direction x relative to the second portion 112 and is adjacent to the second portion 112. The fourth portion 114 is located on the second side x2 in the third direction x relative to the third portion 113 and is adjacent to the third portion 113.

The second metal layer 12 is located on the first side z1 in the first direction z relative to the insulating layer 10. The constituent material of the second metal layer 12 is not particularly limited, and may include, for example, a metal. In the present embodiment, the constituent material of the second metal layer 12 may be the same as that of the first metal layer 11. The second metal layer 12 forms the exposed surface 1a. The exposed surface 1a is a planar surface facing the first side z1 in the first direction z. The exposed surface 1a is exposed from the sealing resin 7. A heat sink 92 shown in FIGS. 10 to 14 may be attached to the exposed surface 1a.

The sealing resin 7 covers the one or more switching elements 2, a portion of the support substrate 1, and a portion of each of the one or more leads 5. The constituent material of the sealing resin 7 is not particularly limited, and an insulating material, such as an epoxy resin or a silicone gel, may be appropriately used.

The sealing resin 7 may have a first resin surface 71, a second resin surface 72, a third resin surface 73, a fourth resin surface 74, a fifth resin surface 75, and a sixth resin surface 76. The second resin surface 72 and the first resin surface 71 face away from each other in the first direction z, and may both be flat surfaces orthogonal to the first direction z. The first resin surface 71 faces the first side z1 in the first direction z, and the second resin surface 72 faces the second side z2 in the first direction z. The exposed surface 1a is exposed from the first resin surface 71. The exposed surface 1a and the first resin surface 71 may be flush with each other, or may be located at different positions in the first direction z. The first resin surface 71 may have a frame shape surrounding the exposed surface 1a in plan view.

The third resin surface 73, the fourth resin surface 74, the fifth resin surface 75, and the sixth resin surface 76 are connected to both the first resin surface 71 and the second resin surface 72, and interposed therebetween in the first direction z. The third resin surface 73 and the fourth resin surface 74 are spaced apart from each other in the third direction x. The third resin surface 73 faces the first side x1 in the third direction x, and the fourth resin surface 74 faces the second side x2 in the third direction x. The fifth resin surface 75 and the sixth resin surface 76 are spaced apart from each other in the second direction y. The fifth resin surface 75 faces the first side y1 in the second direction y, and the sixth resin surface 76 faces the second side y2 in the second direction y.

The sealing resin 7 may have one or more grooves 711. The one or more grooves 711 are recessed from the first resin surface 71 toward the second side z2 in the first direction z. In the illustrated example, the one or more grooves 711 extend in the third direction x. In the illustrated example, the sealing resin 7 has two grooves 711. The two grooves 711 are located on opposite sides in the second direction y with respect to the exposed surface 1a

The sealing resin 7 may have one or more fixing recesses 771. The one or more fixing recesses 771 are recessed in the third direction x. In the illustrated example, the sealing resin 7 has two fixing recesses 771. The two fixing recesses 771 are separately located on opposite sides in the third direction x. As shown in FIG. 14, the fixing recesses 771 may be used, for example, to receive portions of each of screws 921 for fixing the heat sink 92 to the semiconductor device A1. The mounting board 91 may be formed with through-holes 911. The through-holes 911 may receive portions of the screws 921.

The sealing resin 7 may have one or more first recesses 772 and one or more second recesses 773. The one or more first recesses 772 are recessed toward the second side y2 in the second direction y. The one or more second recesses 773 are recessed toward the first side y1 in the second direction y. In the illustrated example, the sealing resin 7 has a plurality of first recesses 772 and a plurality of second recesses 773.

The number, specific configuration, and the like of the one or more switching elements 2 are not particularly limited. In the present embodiment, the one or more switching elements 2 include a first switching element 2A, a second switching element 2B, a third switching element 2C, a fourth switching element 2D, a fifth switching element 2E, and a sixth switching element 2F. The first switching element 2A, the second switching element 2B, the third switching element 2C, the fourth switching element 2D, the fifth switching element 2E, and the sixth switching element 2F may be, for example, MOSFETs (metal-oxide-semiconductor field-effect transistors) including SiC (silicon carbide) substrates (SiC MOSFETs). The first switching element 2A, the second switching element 2B, the third switching element 2C, the fourth switching element 2D, the fifth switching element 2E, and the sixth switching element 2F may be MOSFETs including Si (silicon) substrates instead of SiC substrates. The first switching element 2A, the second switching element 2B, the third switching element 2C, the fourth switching element 2D, the fifth switching element 2E, and the sixth switching element 2F may be, for example, IGBTs or MOSFETs including GaN (gallium nitride).

Each of the first switching element 2A, the second switching element 2B, the third switching element 2C, the fourth switching element 2D, the fifth switching element 2E, and the sixth switching element 2F may have an element body 20, a first electrode 21, a second electrode 22, and a third electrode 23. The element body 20 is a portion that includes, for example, an SiC substrate. The first electrode 21 is located on the first side z1 in the first direction z relative to the element body 20. The second electrode 22 and the third electrode 23 are located on the second side z2 in the first direction z relative to the element body 20. The shapes and arrangement of the first electrode 21, the second electrode 22, and the third electrode 23 are not limited. In the illustrated example, the second electrode 22 is larger than the third electrode 23 as viewed in the first direction z. The second electrode 22 may include two separated regions as viewed in the first direction z. In the present embodiment, when the first switching element 2A, the second switching element 2B, the third switching element 2C, the fourth switching element 2D, the fifth switching element 2E, and the sixth switching element 2F may be MOSFETs including SiC substrates, the first electrode 21 may be a drain electrode, the second electrode 22 may be a source electrode, and the third electrode 23 may be a gate electrode.

The first switching element 2A, the second switching element 2B, and the third switching element 2C are located on the first portion 111. The first switching element 2A, the second switching element 2B, and the third switching element 2C may each be bonded to the first portion 111 with a conductive bonding material 29. The conductive bonding material 29 may be, for example, solder, metal paste, sintered metal, or the like. The first electrodes 21 of the first switching element 2A, the second switching element 2B, and the third switching element 2C are each electrically connected to the first portion 111 with the conductive bonding material 29.

The fourth switching element 2D is located on the second portion 112. The fourth switching element 2D is bonded to the second portion 112 with a conductive bonding material 29. Accordingly, the first electrode 21 of the fourth switching element 2D is electrically connected to the second portion 112 with the conductive bonding material 29.

The fifth switching element 2E is located on the third portion 113. The fifth switching element 2E is bonded to the third portion 113 with a conductive bonding material 29. Accordingly, the first electrode 21 of the fifth switching element 2E is electrically connected to the third portion 113 with the conductive bonding material 29.

The sixth switching element 2F is located on the fourth portion 114. The sixth switching element 2F is bonded to the fourth portion 114 with a conductive bonding material 29. Accordingly, the first electrode 21 of the sixth switching element 2F is electrically connected to the fourth portion 114 with the conductive bonding material 29.

The thermistor 87 is a temperature detection element and may be mounted on, for example, the first metal layer 11. The thermistor 87 is a resistor whose electrical resistance changes significantly with temperature changes, and as its resistance changes according to the ambient temperature, the voltage between its terminals may change. The temperature around the thermistor 87 may be detected based on the voltage between the terminals of the thermistor 87. The characteristics of the thermistor 87 are not limited. The thermistor 87 may be an NTC (negative temperature coefficient) thermistor, a PTC (positive temperature coefficient) thermistor, or a thermistor having other characteristics.

The number and configuration of the one or more leads 5 are not particularly limited. In the present embodiment, the semiconductor device A1 may include, as the one or more leads 5, one or more power leads 5 and one or more control leads 6.

The one or more power leads 5 and the one or more control leads 6 may contain a metal. The metal forming the one or more power leads 5 and the one or more control leads 6 is not particularly limited, and may be, for example, copper, aluminum, iron (Fe), oxygen-free copper, or alloys thereof (for example, Cu—Sn alloys, Cu—Zr alloys, and Cu—Fe alloys). The one or more power leads 5 and the one or more control leads 6 may be plated with nickel (Ni). The one or more power leads 5 and the one or more control leads 6 may be formed, for example, by press working in which a die is pressed against a metal plate, or by patterning a metal plate through etching. The method for forming the one or more power leads 5 and the one or more control leads 6 is not particularly limited. The thicknesses of the one or more power leads 5 and the one or more control leads 6 are not particularly limited, and may be, for example, 0.4 mm or more and 0.8 mm or less. The one or more power leads 5 and the one or more control leads 6 are spaced apart from each other.

In the present embodiment, the one or more power leads 5 include a first power lead 5A, a second power lead 5B, a third power lead 5C, a fourth power lead 5D, and a fifth power lead 5E. The one or more control leads 6 include a first control lead 6A, a second control lead 6B, a third control lead 6C, a fourth control lead 6D, a fifth control lead 6E, a sixth control lead 6F, a seventh control lead 6G, an eighth control lead 6H, a ninth control lead 6J, a tenth control lead 6K, an eleventh control lead 6L, a twelfth control lead 6M, a thirteenth control lead 6P, and a fourteenth control lead 6Q.

In the present embodiment, the first power lead 5A, the second power lead 5B, the third power lead 5C, the fourth power lead 5D, and the fifth power lead 5E form conductive paths to the one or more switching elements 2. The first power lead 5A, the second power lead 5B, the third power lead 5C, the fourth power lead 5D, and the fifth power lead 5E are spaced apart from each other in the third direction x.

The first power lead 5A includes a first power terminal 51A. The first power terminal 51A is the portion of the first power lead 5A that protrudes from the fifth resin surface 75 toward the first side y1 in the second direction y. The first power terminal 51A has a mounting surface 511. The mounting surface 511 faces the second side z2 in the first direction z and is conductively bonded to the mounting board 91 when the semiconductor device A1 is mounted on the mounting board 91, for example. The position of the mounting surface 511 in the first direction z may be the same as that of the second resin surface 72, or may be closer to the second side z2 than the second resin surface 72.

The first power lead 5A may include a first auxiliary terminal 59A. The first auxiliary terminal 59A is located on the first side x1 in the third direction x relative to the first power terminal 51A. The first auxiliary terminal 59A may have a mounting surface 511.

The first power lead 5A may include a pad portion 52A and a bonding portion 53A. The pad portion 52A is located on the second side y2 in the second direction y relative to the first power terminal 51A and covered with the sealing resin 7. The pad portion 52A may be located on the second side z2 in the first direction z relative to the support substrate 1. The pad portion 52A may be spaced apart from the support substrate 1 as viewed in the first direction z. The bonding portion 53A may be located on the second side y2 in the second direction y relative to the pad portion 52A. The bonding portion 53A is conductively bonded to the first portion 111. This conductive bonding may be performed in various ways, such as by using a conductive bonding material or by welding, including laser welding.

The second power lead 5B may be located on the second side x2 in the third direction x relative to the first power lead 5A. The second power lead 5B includes a second power terminal 51B. The second power terminal 51B is the portion of the second power lead 5B that protrudes from the fifth resin surface 75 toward the first side y1 in the second direction y. The second power terminal 51B has a mounting surface 511.

The second power lead 5B may include a pad portion 52B. The pad portion 52B is located on the second side y2 in the second direction y relative to the second power terminal 51B and covered with the sealing resin 7. The pad portion 52B may be located on the second side z2 in the first direction z relative to the support substrate 1. The pad portion 52B may be spaced apart from the support substrate 1 as viewed in the first direction z.

The third power lead 5C may be located between the first power lead 5A and the second power lead 5B in the third direction x. The third power lead 5C includes a third power terminal 51C. The third power terminal 51C is the portion of the third power lead 5C that protrudes from the fifth resin surface 75 toward the first side y1 in the second direction y. The third power terminal 51C has a mounting surface 511.

The third power lead 5C may include a pad portion 52C and a bonding portion 53C. The pad portion 52C is located on the second side y2 in the second direction y relative to the third power terminal 51C and covered with the sealing resin 7. The pad portion 52C may be located on the second side z2 in the first direction z relative to the support substrate 1. The pad portion 52C may be spaced apart from the support substrate 1 as viewed in the first direction z. The bonding portion 53C may be located on the second side y2 in the second direction y relative to the pad portion 52C. The bonding portion 53C is conductively bonded to the second portion 112. This conductive bonding may be performed in various ways, such as by using a conductive bonding material or by welding, including laser welding.

The fourth power lead 5D may be located between the second power lead 5B and the third power lead 5C in the third direction x. The fourth power lead 5D includes a fourth power terminal 51D. The fourth power terminal 51D is the portion of the fourth power lead 5D that protrudes from the fifth resin surface 75 toward the first side y1 in the second direction y. The fourth power terminal 51D has a mounting surface 511.

The fourth power lead 5D may include a pad portion 52D and a bonding portion 53D. The pad portion 52D is located on the second side y2 in the second direction y relative to the fourth power terminal 51D and covered with the sealing resin 7. The pad portion 52D may be located on the second side z2 in the first direction z relative to the support substrate 1. The pad portion 52D may be spaced apart from the support substrate 1 as viewed in the first direction z. The bonding portion 53D may be located on the second side y2 in the second direction y relative to the pad portion 52D. The bonding portion 53D is conductively bonded to the third portion 113. This conductive bonding may be performed in various ways, such as by using a conductive bonding material or by welding, including laser welding.

The fifth power lead 5E may be located between the second power lead 5B and the fourth power lead 5D in the third direction x. The fifth power lead 5E includes a fifth power terminal 51E. The fifth power terminal 51E is the portion of the fifth power lead 5E that protrudes from the fifth resin surface 75 toward the first side y1 in the second direction y. The fifth power terminal 51E has a mounting surface 511.

The fifth power lead 5E may include a pad portion 52E and a bonding portion 53E The pad portion 52E is located on the second side y2 in the second direction y relative to the fifth power terminal 51E and covered with the sealing resin 7. The pad portion 52E may be located on the second side z2 in the first direction z relative to the support substrate 1. The pad portion 52E may be spaced apart from the support substrate 1 as viewed in the first direction z. The bonding portion 53E may be located on the second side y2 in the second direction y relative to the pad portion 52E. The bonding portion 53E is conductively bonded to the fourth portion 114. This conductive bonding may be performed in various ways, such as by using a conductive bonding material or by welding, including laser welding.

The first control lead 6A, the second control lead 6B, the third control lead 6C, the fourth control lead 6D, the fifth control lead 6E, the sixth control lead 6F, the seventh control lead 6G, the eighth control lead 6H, the ninth control lead 6J, the tenth control lead 6K, the eleventh control lead 6L, the twelfth control lead 6M, the thirteenth control lead 6P, and the fourteenth control lead 6Q form transmission paths for control signals for controlling the one or more switching elements 2. The first control lead 6A, the second control lead 6B, the third control lead 6C, the fourth control lead 6D, the fifth control lead 6E, the sixth control lead 6F, the seventh control lead 6G, the eighth control lead 6H, the ninth control lead 6J, the tenth control lead 6K, the eleventh control lead 6L, the twelfth control lead 6M, the thirteenth control lead 6P, and the fourteenth control lead 6Q are spaced apart from each other in the third direction x.

In the illustrated example, a first recess 772 may be located between the first power lead 5A and the third power lead 5C. Another first recess 772 may be located between the third power lead 5C and the fourth power lead 5D. Another first recess 772 may be located between the fourth power lead 5D and the fifth power lead 5E. Still another first recess 772 may be located between the fifth power lead 5E and the second power lead 5B.

The first control lead 6A includes a first control terminal 61A. The first control terminal 61A is the portion of the first control lead 6A that protrudes from the sixth resin surface 76 toward the second side y2 in the second direction y. The first control terminal 61A has a mounting surface 611. The mounting surface 611 faces the second side z2 in the first direction z and is conductively bonded to the mounting board 91 when the semiconductor device A1 is mounted on the mounting board 91, for example. The position of the mounting surface 611 in the first direction z may be the same as that of the second resin surface 72, or may be closer to the second side z2 than the second resin surface 72.

The first control lead 6A may include a pad portion 62A. The pad portion 62A is located on the first side y1 in the second direction y relative to the first control terminal 61A and covered with the sealing resin 7. The pad portion 62A may be located on the second side z2 in the first direction z relative to the support substrate 1. The pad portion 62A may be spaced apart from the support substrate 1 as viewed in the first direction z.

The second control lead 6B may be located on the second side x2 in the third direction x relative to the first control lead 6A. The second control lead 6B includes a second control terminal 61B. The second control terminal 61B is the portion of the second control lead 6B that protrudes from the sixth resin surface 76 toward the second side y2 in the second direction y. The second control terminal 61B has a mounting surface 611.

The second control lead 6B may include a pad portion 62B. The pad portion 62B located on the first side y1 in the second direction y relative to the second control terminal 61B and covered with the sealing resin 7. The pad portion 62B may be located on the second side z2 in the first direction z relative to the support substrate 1. The pad portion 62B may be spaced apart from the support substrate 1 as viewed in the first direction z.

The third control lead 6C may be located on the second side x2 in the third direction x relative to the second control lead 6B. The third control lead 6C includes a third control terminal 61C. The third control terminal 61C is the portion of the third control lead 6C that protrudes from the sixth resin surface 76 toward the second side y2 in the second direction y. The third control terminal 61C has a mounting surface 611.

The third control lead 6C may include a pad portion 62C. The pad portion 62C i located on the first side y1 in the second direction y relative to the third control terminal 61C and covered with the sealing resin 7. The pad portion 62C may be located on the second side z2 in the first direction z relative to the support substrate 1. The pad portion 62C may be spaced apart from the support substrate 1 as viewed in the first direction z.

The fourth control lead 6D may be located on the second side x2 in the third direction x relative to the third control lead 6C. The fourth control lead 6D includes a fourth control terminal 61D. The fourth control terminal 61D is the portion of the fourth control lead 6D that protrudes from the sixth resin surface 76 toward the second side y2 in the second direction y. The fourth control terminal 61D has a mounting surface 611.

The fourth control lead 6D may include a pad portion 62D. The pad portion 62D located on the first side y1 in the second direction y relative to the fourth control terminal 61D and covered with the sealing resin 7. The pad portion 62D may be located on the second side z2 in the first direction z relative to the support substrate 1. The pad portion 62D may be spaced apart from the support substrate 1 as viewed in the first direction z.

The fifth control lead 6E may be located on the second side x2 in the third direction x relative to the fourth control lead 6D. The fifth control lead 6E includes a fifth control terminal 61E. The fifth control terminal 61E is the portion of the fifth control lead 6E that protrudes from the sixth resin surface 76 toward the second side y2 in the second direction y. The fifth control terminal 61E has a mounting surface 611.

The fifth control lead 6E may include a pad portion 62E. The pad portion 62E is located on the first side y1 in the second direction y relative to the fifth control terminal 61E and covered with the sealing resin 7. The pad portion 62E may be located on the second side z2 in the first direction z relative to the support substrate 1. The pad portion 62E may be spaced apart from the support substrate 1 as viewed in the first direction z.

The sixth control lead 6F may be located on the second side x2 in the third direction x relative to the fifth control lead 6E. The sixth control lead 6F includes a sixth control terminal 61F. The sixth control terminal 61F is the portion of the sixth control lead 6F that protrudes from the sixth resin surface 76 toward the second side y2 in the second direction y. The sixth control terminal 61F has a mounting surface 611.

The sixth control lead 6F may include a pad portion 62F. The pad portion 62F is located on the first side y1 in the second direction y relative to the sixth control terminal 61F and covered with the sealing resin 7. The pad portion 62F may be located on the second side z2 in the first direction z relative to the support substrate 1. The pad portion 62F may be spaced apart from the support substrate 1 as viewed in the first direction z.

The seventh control lead 6G may be located on the first side x1 in the third direction x relative to the first control lead 6A. The seventh control lead 6G includes a seventh control terminal 61G. The seventh control terminal 61G is the portion of the seventh control lead 6G that protrudes from the sixth resin surface 76 toward the second side y2 in the second direction y. The seventh control terminal 61G has a mounting surface 611.

The seventh control lead 6G may include a pad portion 62G. The pad portion 62G is located on the first side y1 in the second direction y relative to the seventh control terminal 61G and covered with the sealing resin 7. The pad portion 62G may be located on the second side z2 in the first direction z relative to the support substrate 1. The pad portion 62G may be spaced apart from the support substrate 1 as viewed in the first direction z.

The eighth control lead 6H may be located between the first control lead 6A and the second control lead 6B in the third direction x. The eighth control lead 6H includes an eighth control terminal 61H. The eighth control terminal 61H is the portion of the eighth control lead 6H that protrudes from the sixth resin surface 76 toward the second side y2 in the second direction y. The eighth control terminal 61H has a mounting surface 611.

The eighth control lead 6H may include a pad portion 62H. The pad portion 62H is located on the first side y1 in the second direction y relative to the eighth control terminal 61H and covered with the sealing resin 7. The pad portion 62H may be located on the second side z2 in the first direction z relative to the support substrate 1. The pad portion 62H may be spaced apart from the support substrate 1 as viewed in the first direction z.

The ninth control lead 6J may be located between the second control lead 6B and the third control lead 6C in the third direction x. The ninth control lead 6J includes a ninth control terminal 61J. The ninth control terminal 61J is the portion of the ninth control lead 6J that protrudes from the sixth resin surface 76 toward the second side y2 in the second direction y. The ninth control terminal 61J has a mounting surface 611.

The ninth control lead 6J may include a pad portion 62J. The pad portion 62J is located on the first side y1 in the second direction y relative to the ninth control terminal 61J and covered with the sealing resin 7. The pad portion 62J may be located on the second side z2 in the first direction z relative to the support substrate 1. The pad portion 62J may be spaced apart from the support substrate 1 as viewed in the first direction z.

The tenth control lead 6K may be located between the third control lead 6C and the fourth control lead 6D in the third direction x. The tenth control lead 6K includes a tenth control terminal 61K. The tenth control terminal 61K is the portion of the tenth control lead 6K that protrudes from the sixth resin surface 76 toward the second side y2 in the second direction y. The tenth control terminal 61K has a mounting surface 611.

The tenth control lead 6K may include a pad portion 62K. The pad portion 62K is located on the first side y1 in the second direction y relative to the tenth control terminal 61K and covered with the sealing resin 7. The pad portion 62K may be located on the second side z2 in the first direction z relative to the support substrate 1. The pad portion 62K may be spaced apart from the support substrate 1 as viewed in the first direction z.

The eleventh control lead 6L may be located between the fourth control lead 6D and the fifth control lead 6E in the third direction x. The eleventh control lead 6L includes an eleventh control terminal 61L. The eleventh control terminal 61L is the portion of the eleventh control lead 6L that protrudes from the sixth resin surface 76 toward the second side y2 in the second direction y. The eleventh control terminal 61L has a mounting surface 611.

The eleventh control lead 6L may include a pad portion 62L. The pad portion 62L located on the first side y1 in the second direction y relative to the eleventh control terminal 61L and covered with the sealing resin 7. The pad portion 62L may be located on the second side z2 in the first direction z relative to the support substrate 1. The pad portion 62L may be spaced apart from the support substrate 1 as viewed in the first direction z.

The twelfth control lead 6M may be located between the fifth control lead 6E and the sixth control lead 6F in the third direction x. The twelfth control lead 6M includes a twelfth control terminal 61M. The twelfth control terminal 61M is the portion of the twelfth control lead 6M that protrudes from the sixth resin surface 76 toward the second side y2 in the second direction y. The twelfth control terminal 61M has a mounting surface 611.

The twelfth control lead 6M may include a pad portion 62M. The pad portion 62M is located on the first side y1 in the second direction y relative to the twelfth control terminal 61M and covered with the sealing resin 7. The pad portion 62M may be located on the second side z2 in the first direction z relative to the support substrate 1. The pad portion 62M may be spaced apart from the support substrate 1 as viewed in the first direction z.

The thirteenth control lead 6P may be located on the second side x2 in the third direction x relative to the sixth control lead 6F. The thirteenth control lead 6P includes a thirteenth control terminal 61P. The thirteenth control terminal 61P is the portion of the thirteenth control lead 6P that protrudes from the sixth resin surface 76 toward the second side y2 in the second direction y. The thirteenth control terminal 61P has a mounting surface 611.

The thirteenth control lead 6P may include a pad portion 62P. The pad portion 62P is located on the first side y1 in the second direction y relative to the thirteenth control terminal 61P and covered with the sealing resin 7. The pad portion 62P may be located on the second side z2 in the first direction z relative to the support substrate 1. The pad portion 62P may be spaced apart from the support substrate 1 as viewed in the first direction z.

The fourteenth control lead 6Q may be located between the sixth control lead 6F and the thirteenth control lead 6P in the third direction x. The fourteenth control lead 6Q includes a fourteenth control terminal 61Q. The fourteenth control terminal 61Q is the portion of the fourteenth control lead 6Q that protrudes from the sixth resin surface 76 toward the second side y2 in the second direction y. The fourteenth control terminal 61Q has a mounting surface 611.

The fourteenth control lead 6Q may include a pad portion 62Q. The pad portion 62Q is located on the first side y1 in the second direction y relative to the fourteenth control terminal 61Q and covered with the sealing resin 7. The pad portion 62Q may be located on the second side z2 in the first direction z relative to the support substrate 1. The pad portion 62Q may be spaced apart from the support substrate 1 as viewed in the first direction z.

In FIG. 7, portions indicated by dotted hatching may be plated with, for example, silver.

In the illustrated example, a second recess 773 may be located between the first control lead 6A and the eighth control lead 6H. Another second recess 773 may be located between the second control lead 6B and the ninth control lead 6J. Another second recess 773 may be located between the third control lead 6C and the tenth control lead 6K. Still another second recess 773 may be located between the sixth control lead 6F and the fourteenth control lead 6Q.

The first power terminal 51A, the second power terminal 51B, the third power terminal 51C, the fourth power terminal 51D, and the fifth power terminal 51E include long terminals and short terminals of the present disclosure. In the illustrated example, the third power terminal 51C and the fifth power terminal 51E correspond to the long terminals, and the first power terminal 51A, the second power terminal 51B, and the fourth power terminal 51D correspond to the short terminals. The first auxiliary terminal 59A may be an example of the short terminal.

As shown in FIG. 4, each of the third power terminal 51C and the fifth power terminal 51E, which are long terminals, has a protruding length Lp1 that is longer than a protruding length Lp2 of each of the first power terminal 51A, the second power terminal 51B, and the fourth power terminal 51D, which are short terminals. The specific values of the protruding length Lp1 and the protruding length Lp2 are not particularly limited. The protruding length Lp1 may be, for example, 2 mm or more and 16 mm or less. The protruding length Lp2 may be, for example, 1 mm or more and 15 mm or less. The protruding length Lp1 may be greater than 1 time and not greater than 5 times the protruding length Lp2.

The protruding lengths of the third power terminal 51C and the fifth power terminal 51E may be the same as or different from each other. The protruding lengths of the first power terminal 51A, the second power terminal 51B, and the fourth power terminal 51D may be the same as or different from each other.

The first control terminal 61A, the second control terminal 61B, the third control terminal 61C, the fourth control terminal 61D, the fifth control terminal 61E, the sixth control terminal 61F, the seventh control terminal 61G, the eighth control terminal 61H, the ninth control terminal 61J, the tenth control terminal 61K, the eleventh control terminal 61L, the twelfth control terminal 61M, the thirteenth control terminal 61P, and the fourteenth control terminal 61Q include long terminals and short terminals of the present disclosure. In the illustrated example, the first control terminal 61A, the second control terminal 61B, the third control terminal 61C, the fourth control terminal 61D, the fifth control terminal 61E, the sixth control terminal 61F, and the thirteenth control terminal 61P correspond to the long terminals, and the seventh control terminal 61G, the eighth control terminal 61H, the ninth control terminal 61J, the tenth control terminal 61K, the eleventh control terminal 61L, the twelfth control terminal 61M, and the fourteenth control terminal 61Q correspond to the short terminals.

Each of the first control terminal 61A, the second control terminal 61B, the third control terminal 61C, the fourth control terminal 61D, the fifth control terminal 61E, the sixth control terminal 61F, and the thirteenth control terminal 61P, which are long terminals, has a protruding length Lc1 that is longer than a protruding length Lc2 of each of the seventh control terminal 61G, the eighth control terminal 61H, the ninth control terminal 61J, the tenth control terminal 61K, the eleventh control terminal 61L, the twelfth control terminal 61M, and the fourteenth control terminal 61Q, which are short terminals. The specific values of the protruding length Lc1 and the protruding length Lc2 are not particularly limited. The protruding length Lc1 may be, for example, 2 mm or more and 16 mm or less. The protruding length Lc2 may be, for example, 1 mm or more and 15 mm or less. The protruding length Lc1 may be greater than 1 time and not greater than 5 times the protruding length Lc2.

The protruding lengths of the first control terminal 61A, the second control terminal 61B, the third control terminal 61C, the fourth control terminal 61D, the fifth control terminal 61E, the sixth control terminal 61F, and the thirteenth control terminal 61P may be the same as or different from each other. The protruding lengths of the seventh control terminal 61G, the eighth control terminal 61H, the ninth control terminal 61J, the tenth control terminal 61K, the eleventh control terminal 61L, the twelfth control terminal 61M, and the fourteenth control terminal 61Q may be the same as or different from each other.

In the illustrated example, the long terminals and the short terminals may be alternately arranged in the third direction x. That is, a long terminal may be located between two short terminals. Further, a short terminal may be located between two long terminals.

As shown in FIG. 7, the second electrode 22 of the first switching element 2A may be electrically connected to the pad portion 52C with first conductive connecting members 81. The second electrode 22 of the second switching element 2B may be electrically connected to the pad portion 52D with first conductive connecting members 81. The second electrode 22 of the third switching element 2C may be electrically connected to the pad portion 52E with first conductive connecting members 81. The first conductive connecting members 81 include, for example, a metal such as aluminum (Al) or copper (Cu). The material, shape, number, and the like of the first conductive connecting members 81 are not particularly limited.

The second electrode 22 of the fourth switching element 2D may be electrically connected to the pad portion 52B with first conductive connecting members 81. The second electrode 22 of the fifth switching element 2E may be electrically connected to the pad portion 52B with first conductive connecting members 81. The second electrode 22 of the sixth switching element 2F may be electrically connected to the pad portion 52B with first conductive connecting members 81.

The third electrode 23 of the first switching element 2A may be electrically connected to the pad portion 62A with a second conductive connecting member 82. The third electrode 23 of the second switching element 2B may be electrically connected to the pad portion 62B with a second conductive connecting member 82. The third electrode 23 of the third switching element 2C may be electrically connected to the pad portion 62C with a second conductive connecting member 82. The third electrode 23 of the fourth switching element 2D may be electrically connected to the pad portion 62D with a second conductive connecting member 82. The third electrode 23 of the fifth switching element 2E may be electrically connected to the pad portion 62E with a second conductive connecting member 82. The third electrode 23 of the sixth switching element 2F may be electrically connected to the pad portion 62F with a second conductive connecting member 82. The second conductive connecting members 82 may include, for example, a metal such as gold (Au), silver (Ag), copper (Cu), or aluminum (Al). The material, shape, number, and the like of the second conductive connecting members 82 are not particularly limited.

The second electrode 22 of the first switching element 2A may be electrically connected to the pad portion 62G with a second conductive connecting member 82. The second electrode 22 of the second switching element 2B may be electrically connected to the pad portion 62H with a second conductive connecting member 82. The second electrode 22 of the third switching element 2C may be electrically connected to the pad portion 62J with a second conductive connecting member 82. The second electrode 22 of the fourth switching element 2D may be electrically connected to the pad portion 62K with a second conductive connecting member 82. The second electrode 22 of the fifth switching element 2E may be electrically connected to the pad portion 62L with a second conductive connecting member 82. The second electrode 22 of the sixth switching element 2F may be electrically connected to the pad portion 62M with a second conductive connecting member 82.

Of two portions of the first metal layer 11 that are electrically connected to the thermistor 87, one portion may be electrically connected to the pad portion 62P with a second conductive connecting member 82, and the other portion may be electrically connected to the pad portion 62Q with a second conductive connecting member 82.

As shown in FIG. 15, the semiconductor device A1 may include, for example, a half-bridge switching circuit. The first switching element 2A, the second switching element 2B, and the third switching element 2C may form an upper-arm circuit, and the fourth switching element 2D, the fifth switching element 2E, and the sixth switching element 2F may form a lower-arm circuit. In the upper-arm circuit, the first switching element 2A, the second switching element 2B, and the third switching element 2C may be connected in parallel with each other. In the lower-arm circuit, the fourth switching element 2D, the fifth switching element 2E, and the sixth switching element 2F may be connected in parallel with each other. Each of the first switching element 2A, the second switching element 2B, and the third switching element 2C and a corresponding one of the fourth switching element 2D, the fifth switching element 2E, and the sixth switching element 2F may be connected in series with each other to form a bridge circuit. A DC voltage to be converted may be inputted to the first power terminal 51A and the second power terminal 51B. The first power terminal 51A may be a positive electrode (P terminal), and the second power terminal 51B may be a negative electrode (N terminal). The AC voltage converted by the first switching element 2A to the sixth switching element 2F may be outputted from the third power terminal 51C, the fourth power terminal 51D, and the fifth power terminal 51E.

The first control terminal 61A may be a gate terminal of the first switching element 2A, and the seventh control terminal 61G may be a source sense terminal of the first switching element 2A. The second control terminal 61B may be a gate terminal of the second switching element 2B, and the eighth control terminal 61H may be a source sense terminal of the second switching element 2B. The third control terminal 61C may be a gate terminal of the third switching element 2C, and the ninth control terminal 61J may be a source sense terminal of the third switching element 2C.

The fourth control terminal 61D may be a gate terminal of the fourth switching element 2D, and the tenth control terminal 61K may be a source sense terminal of the fourth switching element 2D. The fifth control terminal 61E may be a gate terminal of the fifth switching element 2E, and the eleventh control terminal 61L may be a source sense terminal of the fifth switching element 2E. The sixth control terminal 61F may be a gate terminal of the sixth switching element 2F, and the twelfth control terminal 61M may be a source sense terminal of the sixth switching element 2F.

The thirteenth control terminal 61P and the fourteenth control terminal 61Q may be terminals for temperature detection using the thermistor 87.

Next, the effects of the semiconductor device A1 will be described.

The mounting surface 511 and the mounting surface 611 face the second side z2 in the first direction z. As shown in FIGS. 10 to 14, the semiconductor device A1 can be surface-mounted on the mounting board 91 using the mounting surface 511 and the mounting surface 611. Accordingly, it is not necessary to insert the first power terminal 51A, the first control terminal 61A, and the like into through-holes of the mounting board 91. Therefore, the efficiency of mounting work can be improved.

The semiconductor device A1 has long terminals and short terminals. Among the plurality of mounting surfaces 511, the mounting surfaces 511 of the long terminals and the mounting surfaces 511 of the short terminals are spaced apart from each other in the second direction y. This improves mounting strength when the semiconductor device A1 is surface-mounted on the mounting board 91 or the like. Among the plurality of mounting surfaces 611, the mounting surfaces 611 of the long terminals and the mounting surfaces 611 of the short terminals are spaced apart from each other in the second direction y. This can improve mounting strength when the semiconductor device A1 is surface-mounted on the mounting board 91 or the like.

As shown in FIGS. 6 and 7, the long terminals and the short terminals are alternately arranged in the third direction x. This can further improve mounting strength of the semiconductor device A1.

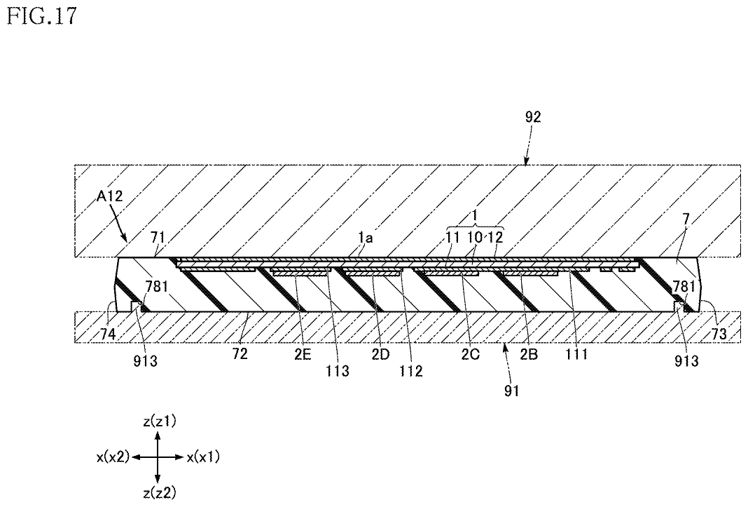

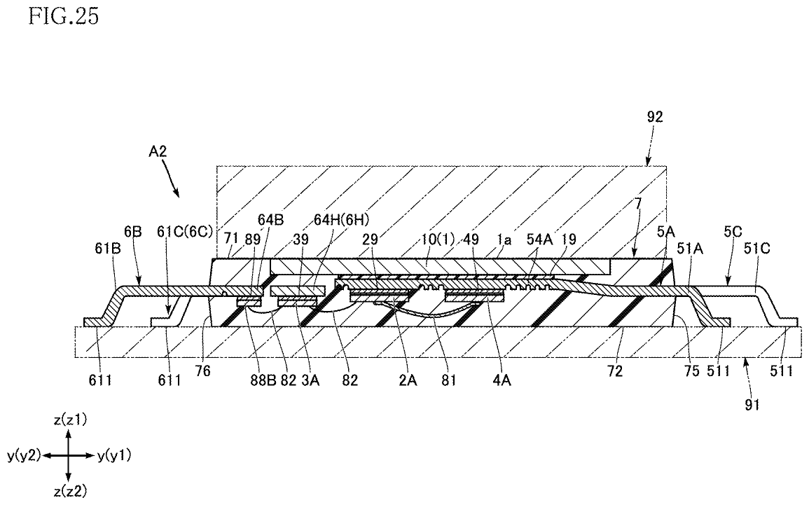

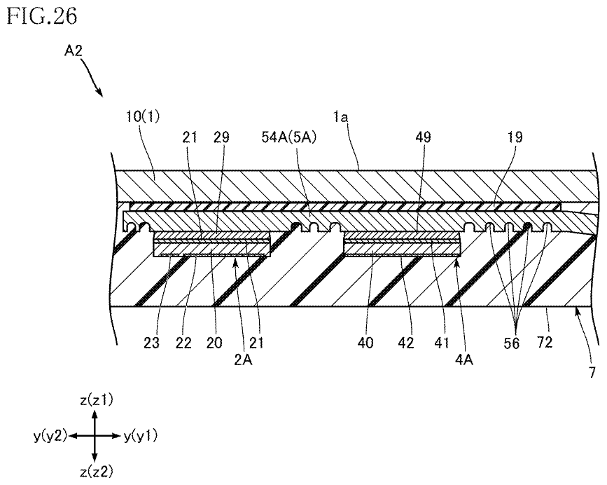

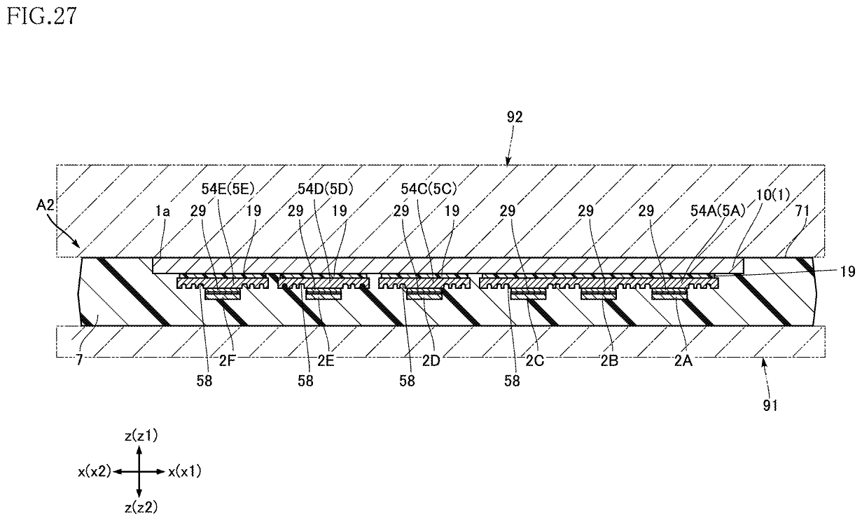

FIGS. 16 to 28 show variations and other embodiments of the present disclosure In these figures, the elements that are identical or similar to those of the embodiment described above are denoted by the same reference signs, and the descriptions thereof are omitted. Various parts of variations and embodiments may be selectively used in any appropriate combination as long as it is technically compatible.

The semiconductor device according to the present disclosure is not limited to the above-described embodiments. Various modifications in design may be made freely in the specific structure of each part of the semiconductor device according to the present disclosure.

### First Embodiment, First Variation

FIG. 16 shows a first variation of the semiconductor device A1. In the semiconductor device A11 according to the present variation, irregularities may be provided on the first portion 111, the second portion 112, the third portion 113, and the fourth portion 114. The irregularities may be formed by performing laser processing, etching, or the like on the surfaces of the first portion 111, the second portion 112, the third portion 113, and the fourth portion 114. The irregularities may not be provided in the respective regions of the first portion 111, the second portion 112, the third portion 113, and the fourth portion 114 on which the first switching element 2A to the sixth switching element 2F are mounted.

The present variation can improve the efficiency of mounting work. According to the present variation, since irregularities are provided on the first portion 111, the second portion 112, the third portion 113, and the fourth portion 114, delamination between the first portion 111, the second portion 112, the third portion 113 and the fourth portion 114, and the sealing resin 7 can be suppressed.

### First Embodiment, Second Variation

FIG. 17 shows a second variation of the semiconductor device A1. In the semiconductor device A12 according to the present variation, the sealing resin 7 may have one or more first engaging portions 781. Each of the one or more first engaging portions 781 may engage with, for example, a corresponding one of one or more third engaging portions 913 provided on the mounting board 91 to suppress or prevent movement of the semiconductor device A12 relative to the mounting board 91 in a direction intersecting the first direction z. In the present example, each of the one or more first engaging portion 781 is a recess that is recessed from the second resin surface 72 toward the first side z1 in the first direction z.

### First Embodiment, Third Variation

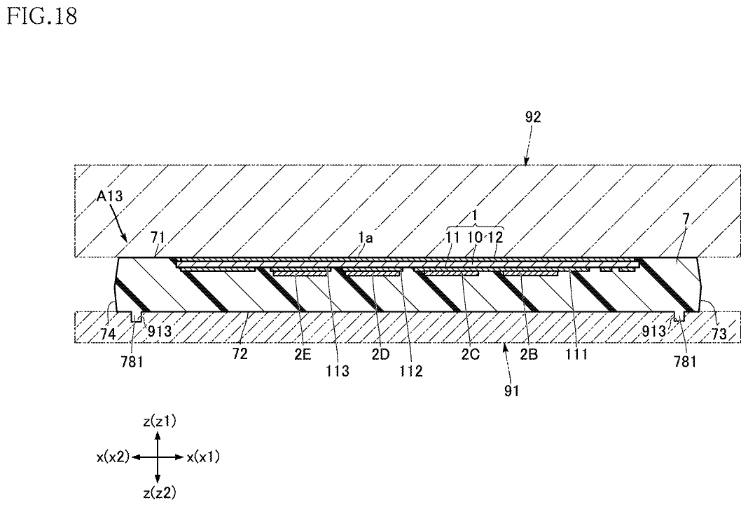

FIG. 18 shows a third variation of the semiconductor device A1. In the semiconductor device A13 according to the present variation, the first engaging portion 781 is a protrusion protruding from the second resin surface 72 toward the second side z2 in the first direction z.

These variations can improve the efficiency of mounting work. According to the variations, when the semiconductor devices A12 and A13 are surface-mounted on the mounting board 91, unintended movement of the semiconductor devices A12 and A13 in a direction intersecting the first direction z can be reduced from placement of the semiconductor devices A12 and A13 on the mounting board 91 until completion of the surface mounting by reflowing.

### First Embodiment, Fourth Variation

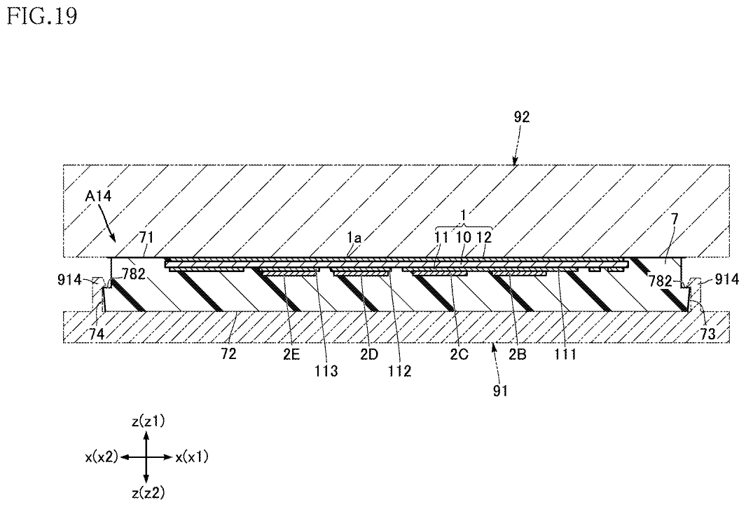

FIG. 19 shows a fourth variation of the semiconductor device A1. In the semiconductor device A14 according to the present variation, the sealing resin 7 may have one or more second engaging portions 782. Each of the second engaging portions 782 may engage with, for example, a corresponding one of one or more fourth engaging portions 914 provided on the mounting board 91 to generate a force that urges the semiconductor device A14 toward the mounting board 91 in the first direction z.

The present variation can improve the efficiency of mounting work. According to the present variation, when the semiconductor device A14 is surface-mounted on the mounting board 91, a force that presses the semiconductor device A14 against the mounting board 91 can be applied from placement of the semiconductor device A14 on the mounting board 91 until completion of the surface mounting by reflowing. This can reduce unintended movement of the semiconductor device A14 in a direction intersecting the first direction z. Before the semiconductor device A14 is placed on the mounting board 91, the mounting surfaces 511 and the mounting surfaces 611 may be located on the second side z2 in the first direction z relative to the second resin surface 72. In this case, engagement between the second engaging portion 782 and the fourth engaging portion 914 causes the power terminals 51 and the control terminals 61 to be slightly bent. This can prevent the power terminals 51 and the control terminals 61 from separating from the mounting board 91 toward the first side z1 in the first direction z.

### First Embodiment, Fifth Variation

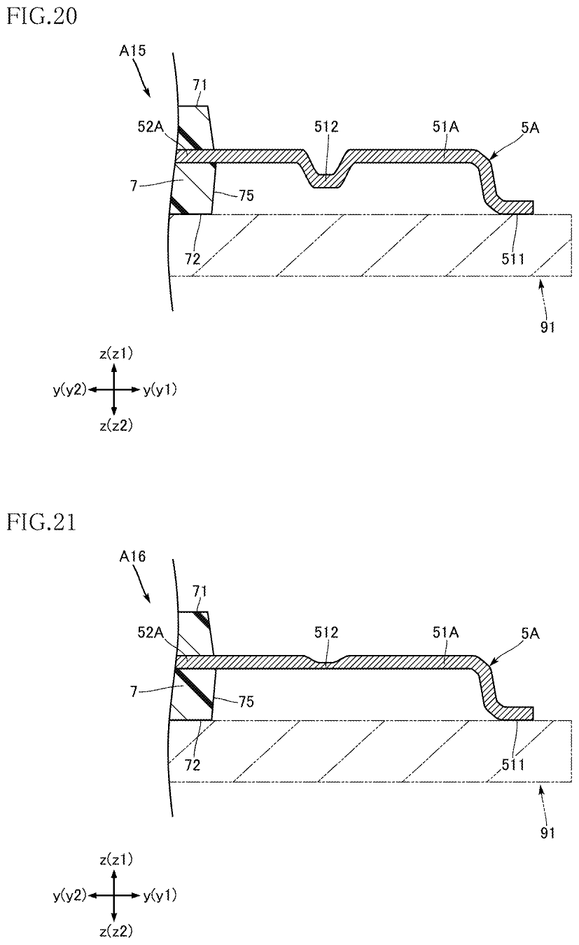

FIG. 20 shows a fifth variation of the semiconductor device A1. In the semiconductor device A15 according to the present variation, one or more leads (the first power lead 5A in the illustrated example) may have a resilient portion 512. The resilient portion 512 is the portion that allows elastic deformation of the first power terminal 51A in the second direction y. In the illustrated example, the resilient portion 512 is provided by bending a portion of the first power terminal 51A.

### First Embodiment, Sixth Variation

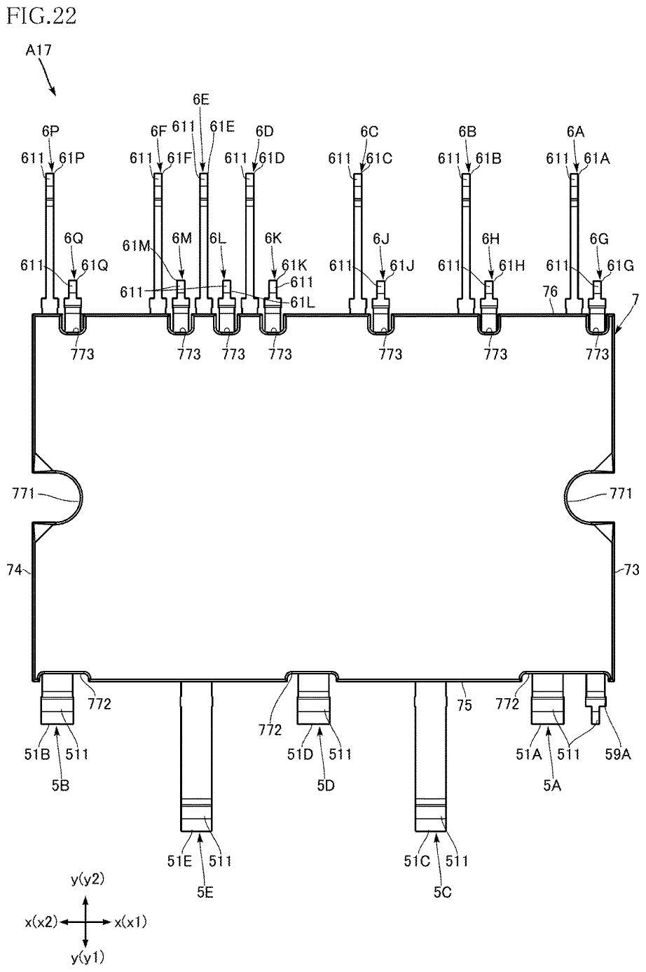

FIG. 21 shows a sixth variation of the semiconductor device A1. In the semiconductor device A16 according to the present variation, the resilient portion 512 is provided by making a portion of the first power terminal 51A thinner.

These variations can improve the efficiency of mounting work. According to these variations, the first power terminal 51A easily deforms elastically in the second direction y. This can prevent excessive force from acting on solder or the like conductively bonding the mounting surface 511 to the mounting board 91 when thermal stress or the like acts on the first power terminal 51A during use of the semiconductor devices A15 and A16 after mounting. The resilient portion 512 may be provided on other power terminals 51 and other control terminals 61.

### First Embodiment, Seventh Variation

FIG. 22 shows a seventh variation of the semiconductor device A1. In the semiconductor device A17 according to the present variation, the first power terminal 51A, the fourth power terminal 51D, and the second power terminal 51B individually protrude from the plurality of first recesses 772 toward the first side y1 in the second direction y. The first power terminal 51A, the fourth power terminal 51D, and the second power terminal 51B correspond to the short terminals of the present disclosure.

The seventh control terminal 61G, the eighth control terminal 61H, the ninth control terminal 61J, the tenth control terminal 61K, the eleventh control terminal 61L, the twelfth control terminal 61M, and the fourteenth control terminal 61Q individually protrude from the plurality of second recesses 773 toward the second side y2 in the second direction y. The seventh control terminal 61G, the eighth control terminal 61H, the ninth control terminal 61J, the tenth control terminal 61K, the eleventh control terminal 61L, the twelfth control terminal 61M, and the fourteenth control terminal 61Q correspond to the short terminals of the present disclosure.

The present variation can improve the efficiency of mounting work. According to the present variation, the mounting surfaces 511 and the mounting surfaces 611 of the short terminals can be positioned closer to the sealing resin 7 in the second direction y. As a result, it is possible to shorten the long terminals without changing the distance between the mounting surfaces 511 of the long terminals and the mounting surfaces 511 of the short terminals. It is also possible to shorten the long terminals without changing the distance between the mounting surfaces 611 of the long terminals and the mounting surfaces 611 of the short terminals. Accordingly, the space required for mounting the semiconductor device A17 can be reduced.

### First Embodiment, Eighth Variation

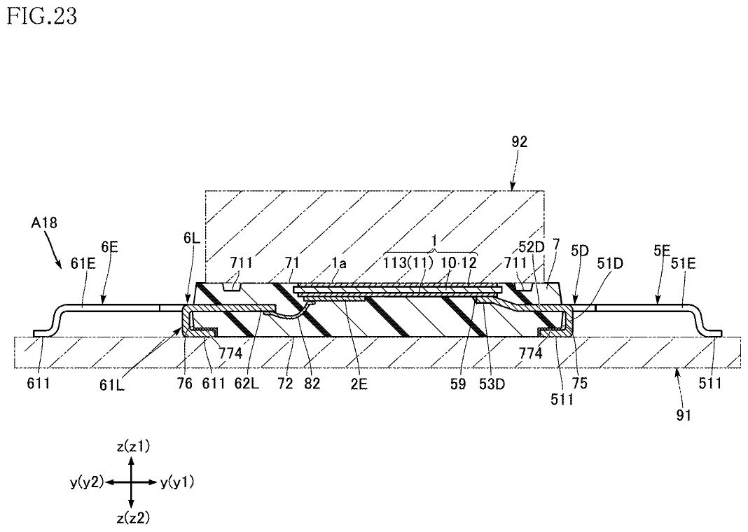

FIG. 23 shows an eighth variation of the semiconductor device A1. In the semiconductor device A18 according to the present variation, the fourth power terminal 51D is bent such that the mounting surface 511 overlaps with the sealing resin 7 as viewed in the first direction z. The sealing resin 7 may have accommodation recesses 774. The accommodation recesses 774 are recessed from the second resin surface 72 toward the first side z1 in the first direction z and open in the second direction y. The distal end of the fourth power terminal 51D that includes the mounting surface 511 may be received in one of the accommodation recesses 774. Other short terminals may have the same configuration as that of the fourth power terminal 51D.

The eleventh control terminal 61L is bent such that the mounting surface 611 overlaps with the sealing resin 7 as viewed in the first direction z. The distal end of the eleventh control terminal 61L that includes the mounting surface 611 may be received in another one of the accommodation recesses 774. Other short terminals may have the same configuration as that of the eleventh control terminal 61L.

The present variation can improve the efficiency of mounting work. According to the present variation, similarly to the semiconductor device A17, the space required for mounting the semiconductor device A18 can be reduced.

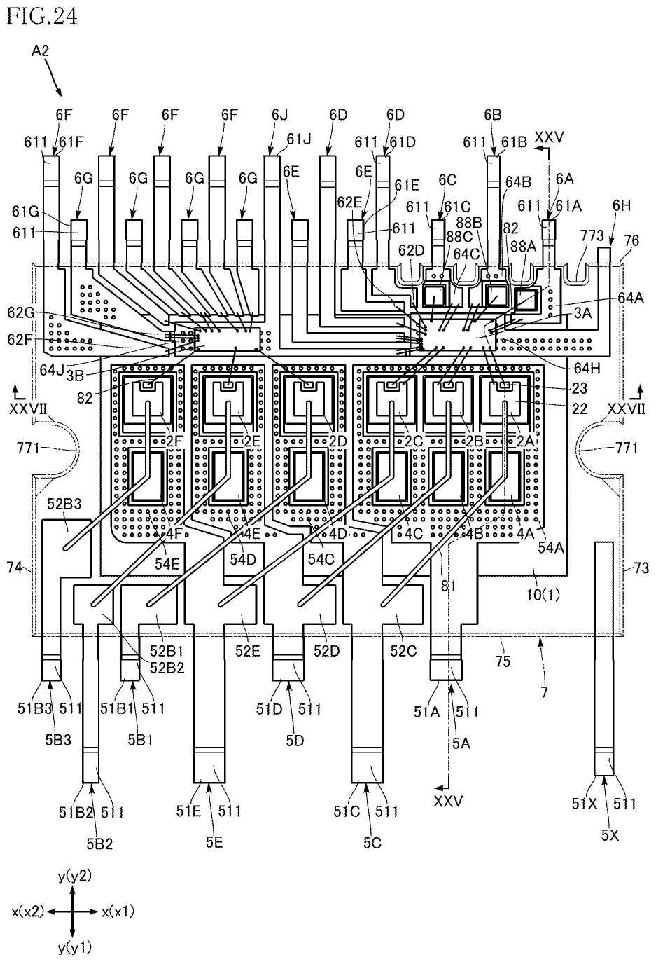

FIGS. 24 to 28 show a semiconductor device according to a second embodiment of the present disclosure. The semiconductor device A2 according to the present embodiment may include a first control element 3A and a second control element 3B. The semiconductor device A2 may be configured as, for example, an IPM (Intelligent Power Module) that performs drive control of an inverter motor.

The first control element 3A and the second control element 3B may be control semiconductor elements. In the present disclosure, the control semiconductor element refers to an element that functions to control operations of the first switching element 2A to the sixth switching element 2F and may be, for example, a driver IC. In the present embodiment, both the first control element 3A and the second control element 3B are driver ICs. The first control element 3A may be a high-voltage-side driver IC that handles a relatively high-voltage current, and the second control element 3B may be a low-voltage-side driver IC that handles a relatively low-voltage current.

The support substrate 1 of the semiconductor device A2 may include an insulating layer 10. The exposed surface 1a may be provided by the insulating layer 10.

The first power lead 5A may include an island portion 54A. The island portion 54A is bonded to the insulating layer 10 via a bonding layer 19. The bonding layer 19 may be, for example, an insulating bonding material or a conductive bonding material. Each of the first electrodes 21 of the first switching element 2A, the second switching element 2B, and the third switching element 2C is conductively bonded to the island portion 54A with the corresponding conductive bonding material 29.

The third power lead 5C may include an island portion 54C. The island portion 54C bonded to the insulating layer 10 via a bonding layer 19. The first electrode 21 of the fourth switching element 2D is conductively bonded to the island portion 54C with the corresponding conductive bonding material 29.

The fourth power lead 5D may include an island portion 54D. The island portion 54D is bonded to the insulating layer 10 via a bonding layer 19. The first electrode 21 of the fifth switching element 2E is conductively bonded to the island portion 54D with the corresponding conductive bonding material 29.

The fifth power lead 5E may include an island portion 54E. The island portion 54E is bonded to the insulating layer 10 via a bonding layer 19. The first electrode 21 of the sixth switching element 2F is conductively bonded to the island portion 54E with the corresponding conductive bonding material 29.

The island portion 54A, the island portion 54B, the island portion 54C, the island portion 54D, and the island portion 54E may have a plurality of recesses 56. The recesses 56 may be formed by, for example, laser processing, etching, or the like.

The semiconductor device A2 may include a first diode 4A, a second diode 4B, a third diode 4C, a fourth diode 4D, a fifth diode 4E, and a sixth diode 4F. The first diode 4A, the second diode 4B, the third diode 4C, the fourth diode 4D, the fifth diode 4E, and the sixth diode 4F may be, for example, FRDs (Fast Recovery Diodes). The first diode 4A, the second diode 4B, the third diode 4C, the fourth diode 4D, the fifth diode 4E, and the sixth diode 4F may have an element body 40, an electrode 41, and an electrode 42.

Each of the electrodes 41 of the first diode 4A, the second diode 4B, and the third diode 4C may be conductively bonded to the island portion 54A with a conductive bonding material 49.

The electrode 41 of the fourth diode 4D may be conductively bonded to the island portion 54C with the conductive bonding material 49. The electrode 41 of the fifth diode 4E may be conductively bonded to the island portion 54D with the conductive bonding material 49. The electrode 41 of the sixth diode 4F may be conductively bonded to the island portion 54E with the conductive bonding material 49.

The semiconductor device A2 may include a second power lead 5B1, a second power lead 5B2, and a second power lead 5B3. The second power lead 5B1 may include a second power terminal 51B1. The second power lead 5B2 may include a second power terminal 51B2. The second power lead 5B3 may include a second power terminal 51B3. The second power terminal 51B1, the second power terminal 51B2, and the second power terminal 51B3 protrude from the fifth resin surface 75 toward the first side y1 in the second direction y.

The semiconductor device A2 may include a dummy lead 5X. The dummy lead 5X may include a dummy terminal 51X. The dummy terminal 51X may have a mounting surface 511.

In the present embodiment, the third power terminal 51C, the fifth power terminal 51E, and the second power terminal 51B2 correspond to the long terminals of the present disclosure, and the first power terminal 51A, the fourth power terminal 51D, the second power terminal 51B1, and the second power terminal 51B3 correspond to the short terminals. The dummy terminal 51X may correspond to the long terminal of the present disclosure.

The second power lead 5B1 may include a pad portion 52B1. The second power lead 5B2 may include a pad portion 52B2. The second power lead 5B3 may include a pad portion 52B3. The pad portion 52B1, the pad portion 52B2, and the pad portion 52B3 are covered with the sealing resin 7.

The second electrode 22 of the first switching element 2A, the electrode 42 of the first diode 4A, and the pad portion 52C may be electrically connected to each other with a first conductive connecting member 81. The second electrode 22 of the second switching element 2B, the electrode 42 of the second diode 4B, and the pad portion 52D may be electrically connected to each other with a first conductive connecting member 81. The second electrode 22 of the third switching element 2C, the electrode 42 of the third diode 4C, and the pad portion 52E may be electrically connected to each other with a first conductive connecting member 81.

The second electrode 22 of the fourth switching element 2D, the electrode 42 of the fourth diode 4D, and the pad portion 52B1 may be electrically connected to each other with a first conductive connecting member 81. The second electrode 22 of the fifth switching element 2E, the electrode 42 of the fifth diode 4E, and the pad portion 52B2 may be electrically connected to each other with a first conductive connecting member 81. The second electrode 22 of the sixth switching element 2F, the electrode 42 of the sixth diode 4F, and the pad portion 52B3 may be electrically connected to each other with a first conductive connecting member 81.

The semiconductor device A2 may include a first control lead 6A to a ninth control lead 6J.

The eighth control lead 6H may include an island portion 64H. The island portion 64H may be bonded to the insulating layer 10 with the bonding layer 19. The first control element 3A may be mounted on the island portion 64H.

The ninth control lead 6J may include an island portion 64J. The island portion 64J may be bonded to the insulating layer 10 with the bonding layer 19. The second control element 3B may be mounted on the island portion 64J.

The first control lead 6A, the second control lead 6B, and the third control lead 6C may individually include an island portion 64A, an island portion 64B, and an island portion 64C. A diode 88A may be mounted on the island portion 64A. A diode 88B may be mounted on the island portion 64B. A diode 88C may be mounted on the island portion 64C.

The second control terminal 61B, the fourth control terminal 61D, the sixth control terminal 61F, and the ninth control terminal 61J correspond to the long terminals of the present disclosure. The first control terminal 61A, the third control terminal 61C, the two fifth control terminals 61E, and the plurality of seventh control leads 6G correspond to the short terminals of the present disclosure.

The second electrodes 22 and the third electrodes 23 of the first switching element 2A, the second switching element 2B, and the third switching element 2C may be electrically connected to the first control element 3A with second conductive connecting members 82. The second electrodes 22 and the third electrodes 23 of the fourth switching element 2D, the fifth switching element 2E, and the sixth switching element 2F may be electrically connected to the second control element 3B with second conductive connecting members 82.

The diode 88A, the diode 88B, and the diode 88C may be electrically connected to the first control element 3A with second conductive connecting members 82. The island portion 64A, the island portion 64B, and the island portion 64C may be connected to the first control element 3A with second conductive connecting members 82.

The pad portion 62D and the plurality of pad portions 62E may be electrically connected to the first control element 3A with second conductive connecting members 82.

The plurality of pad portions 62F and the plurality of pad portions 62G may be electrically connected to the second control element 3B with second conductive connecting members 82.

The sealing resin 7 may have a plurality of second recesses 773. Each of the second recesses 773 may be located between adjacent ones of the first control terminal 61A, the second control terminal 61B, the third control terminal 61C, and the fourth control terminal 61D.

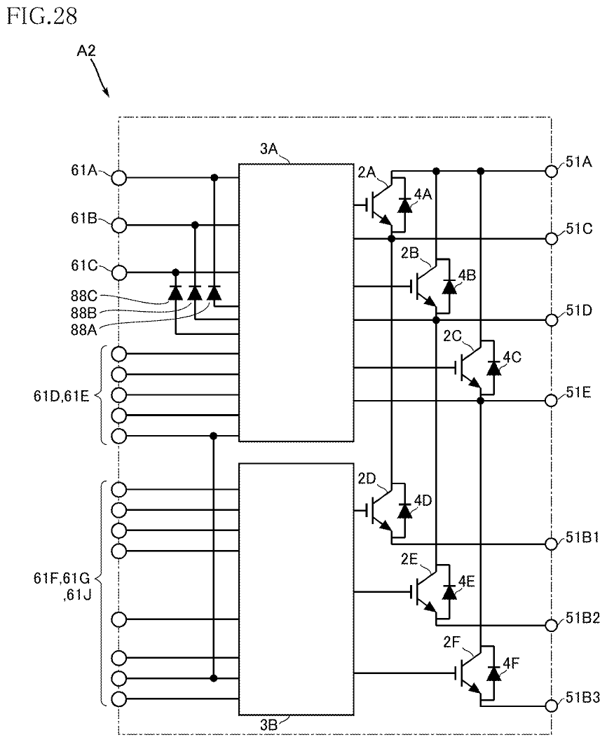

FIG. 28 shows an example of a circuit diagram of the semiconductor device A2. DC power is inputted to the first power terminal 51A and the second power terminals 51B1, 51B2, and 51B3. AC power is outputted from the third power terminal 51C, the fourth power terminal 51D, and the fifth power terminal 51E. The first control terminal 61A, the second control terminal 61B, the third control terminal 61C, the fourth control terminals 61D, and the fifth control terminals 61E are used, for example, for inputting control signals to the first control element 3A. The sixth control terminals 61F, the seventh control terminals 61G, and the ninth control terminal 61J are used, for example, for inputting control signals to the second control element 3B.

The present embodiment can improve the efficiency of mounting work. As understood from the present embodiment, the semiconductor device of the present disclosure may be configured to incorporate a driver IC or the like for driving and controlling the switching elements.

Clause 1.

A semiconductor device (A1) comprising:
one or more switching elements (2A);
a support substrate (1) supporting the one or more switching elements (2A);
one or more leads (5A); and
a sealing resin (7) covering the one or more switching elements (2A), a part of the support substrate (1), and a part of each of the one or more leads (5A),
wherein the support substrate (1) includes an exposed surface (1a) exposed from the sealing resin (7) on a first side (z1) in a first direction (z) that is a thickness direction of the support substrate (1), and
each of the one or more leads (5A) includes a terminal (51A) including a mounting surface (511) facing a second side (z2) in the first direction (z).

Clause 2.

The semiconductor device (A1) according to clause 1, wherein the one or more terminals include a long terminal (51C) and a short terminal (51A) that protrude in a second direction (y) intersecting the first direction (z), and
a protruding length of the long terminal (51C) from the sealing resin (7) is longer than a protruding length of the short terminal (51A) from the sealing resin (7).

Clause 3.

The semiconductor device (A1) according to clause 1 or 2, wherein the support substrate (1) includes an insulating layer (10).

Clause 4.

The semiconductor device (A1) according to clause 3, wherein the support substrate (1) includes a first metal layer (11) located on the second side (z2) in the first direction (z) relative to the insulating layer (10), and
the one or more switching elements (2A) are conductively bonded to the first metal layer (11).

Clause 5.

The semiconductor device (A1) according to clause 4, wherein the support substrate (1) includes a second metal layer (12) located on the first side (z1) in the first direction (z) relative to the insulating layer (10), and
the exposed surface (1a) is provided by the second metal layer (12).

Clause 6.

The semiconductor device (A2) according to clause 3, wherein the exposed surface (1a) is provided by the insulating layer (10).

Clause 7.

The semiconductor device (A12) according to any one of clauses 1 to 6, wherein the sealing resin (7) includes a first engaging portion (781) configured to position the semiconductor device relative to a mounting target in a direction intersecting the first direction (z).

Clause 8.

The semiconductor device (A14) according to any one of clauses 1 to 7, wherein the sealing resin (7) includes a second engaging portion (782) configured to generate a force toward a mounting target in the first direction (z).

Clause 9.

The semiconductor device (A15) according to clause 2, wherein the terminal (51A) includes a resilient portion (512) that allows elastic deformation in the second direction (y).

Clause 10.

The semiconductor device (A1) according to any one of clauses 1 to 9, wherein one or more terminals include a first power terminal (51A) for carrying a current to be switched by the one or more switching elements (2A).

Clause 11.

The semiconductor device (A1) according to any one of clauses 1 to 10, wherein the one or more terminals include a first control terminal (61A) for switching control of the one or more switching elements (2A).

Clause 12.

The semiconductor device (A1) according to clause 2, wherein the sealing resin (7) includes a first recess (772) recessed in the second direction (y).

Clause 13.

The semiconductor device (A17) according to clause 12, wherein the short terminal (51A) protrudes from the first recess (772).

Clause 14.

The semiconductor device (A18) according to clause 2, wherein the short terminal (51D) is bent such that the mounting surface (511) overlaps with the sealing resin (7) as viewed in the first direction.

Clause 15.

The semiconductor device (A2) according to any one of clauses 1 to 14, further comprising one or more control elements (3A) that control switching of the one or more switching elements (2A).

Clause 16.

The semiconductor device (A2) according to clause 6, wherein the one or more leads (5A) include an island portion (54A) on which the one or more switching elements (2A) are mounted, and
the island portion (54a) is bonded to the insulating layer (10).

Clause 17.

The semiconductor device (A1) according to clause 2, wherein a distance in the second direction (y) between the mounting surface (511) of the long terminal and the sealing resin (7) is greater than 1 time and not greater than 5 times a distance in the second direction (y) between the mounting surface (511) of the short terminal and the sealing resin (7).

1. A semiconductor device comprising:
one or more switching elements;
a support substrate supporting the one or more switching elements;
one or more leads; and
a sealing resin covering the one or more switching elements, a part of the support substrate, and a part of each of the one or more leads,
wherein the support substrate includes an exposed surface exposed from the sealing resin on a first side in a first direction that is a thickness direction of the support substrate, and
each of the one or more leads includes a terminal including a mounting surface facing a second side in the first direction.

2. The semiconductor device according to claim 1, wherein the one or more terminals include a long terminal and a short terminal that protrude in a second direction intersecting the first direction, and
a protruding length of the long terminal from the sealing resin is longer than a protruding length of the short terminal from the sealing resin.

3. The semiconductor device according to claim 1, wherein the support substrate includes an insulating layer.

4. The semiconductor device according to claim 3, wherein the support substrate includes a first metal layer located on the second side in the first direction relative to the insulating layer, and
the one or more switching elements are conductively bonded to the first metal layer.

5. The semiconductor device according to claim 4, wherein the support substrate includes a second metal layer located on the first side in the first direction relative to the insulating layer, and
the exposed surface is provided by the second metal layer.

6. The semiconductor device according to claim 3, wherein the exposed surface is provided by the insulating layer.

7. The semiconductor device according to claim 1, wherein the sealing resin includes a first engaging portion configured to position the semiconductor device relative to a mounting target in a direction intersecting the first direction.

8. The semiconductor device according to claim 1, wherein the sealing resin includes a second engaging portion configured to generate a force toward a mounting target in the first direction.

9. The semiconductor device according to claim 2, wherein the terminal includes a resilient portion that allows elastic deformation in the second direction.

10. The semiconductor device according to claim 1, wherein the one or more terminals include a first power terminal for carrying a current to be switched by the one or more switching elements.

11. The semiconductor device according to claim 1, wherein the one or more terminals include a first control terminal for switching control of the one or more switching elements.

12. The semiconductor device according to claim 2, wherein the sealing resin includes a first recess recessed in the second direction.

13. The semiconductor device according to claim 12, wherein the short terminal protrudes from the first recess.

14. The semiconductor device according to claim 2, wherein the short terminal is bent such that the mounting surface overlaps with the sealing resin as viewed in the first direction.

15. The semiconductor device according to claim 1, further comprising one or more control elements that control switching of the one or more switching elements.
